(19) United States
(12) Patent Application Publication
(10) Pub. No.: US 2010/0185409 A1
(43) Pub. Date: Jul. 22, 2010

(54) SIGNAL PROCESSING APPARATUS FOR COMPUTING POSITION OR ANGLE OF TARGET OBJECT

(75) Inventor: Yuzo Seo, Kamakura-shi (JP)

Correspondence Address: ROSSI, KIMMS & McDOWELL LLP., 20609 Gordon Park Square, Suite 150, Ashburn, VA, 20147, US

(73) Assignee: CANON KABUSHIKI KAISHA, Tokyo (JP)

(21) Appl. No.: 12/688,487

(22) Filed: Jan. 15, 2010

(30) Foreign Application Priority Data
Jan. 19, 2009 (JP) 2009-009365

(51) Int. Cl. G06F 19/00; G01R 35/00

(52) U.S. Cl. 702/106; 702/151

(57) ABSTRACT

A signal processing apparatus which computes a position or angle of a target object based on a first phase signal (A), a first reversed phase signal (A′) having a phase opposite to that of the first phase signal (A), a second phase signal (B) having a phase different from that of the first phase signal (A), and a second reversed phase signal (B′) having a phase opposite to that of the second phase signal (B) which are provided by a detecting apparatus that detects the position or angle of the target object, comprises a first computing unit which computes (A−A′)/(A+A′) as a cosine signal and (B−B′)/(B+B′) as a sine signal, and a second computing unit which computes the position or angle of the target object based on the cosine signal and the sine signal.

### BACKGROUND OF THE INVENTION

1. Field of the Invention

The present invention relates to a signal processing apparatus for computing the position or angle of a target object based on periodic signals provided by a detecting apparatus.

2. Description of the Related Art

For the purpose of measuring the position or angle of a target object, a detecting apparatus such as an encoder or a laser interferometer is used. The detecting apparatus outputs sinusoidal periodic signals whose phases change in accordance with the position or angle of a target object and generate a phase difference of 90°. Arctangent computation of the periodic signals output from the detecting apparatus and having the phase difference of 90° enables accurate detection of the position or angle of the target object.

A periodic signal output from the detecting apparatus normally contains error components such as an offset error, amplitude error, and phase difference error, unlike an ideal sine wave. U.S. Pat. No. 4,458,322 discloses a technique for correcting such error components.

In transmission lines that connect the detecting apparatus to the signal processing apparatus for processing periodic signals output from it, noise can be superimposed on the periodic signals. To remove the noise, a technique is used which transmits a phase signal and a reversed phase signal as periodic signals and subtracts the reversed phase signal from the phase signal on the receiving side. According to this technique, it is possible to cancel noises which are equally superimposed in the transmission line for transmitting the phase signal and the transmission line for transmitting the reversed phase signal. A phase signal and reversed phase signal can be generated by inverting and amplifying a single signal. Instead, two detectors may be provided to output a phase signal and reversed phase signal.

A periodic signal output from a detecting apparatus such as an encoder or a laser interferometer contains amplitude modulation noise. The amplitude modulation noise can be generated due to, for example, fluctuations in the intensity of light generated by a light source or noise applied to the power supply voltage of a photoreceiving circuit and an electronic circuit for amplifying the signal output from the photoreceiving circuit.

Since arctangent computation calculates the ratio of the values of two periodic signals, the amplitude modulation noise does not influence the result. However, the peak value of a periodic signal to be used to correct an offset error or amplitude error is sensitive to the amplitude modulation noise. To correct an offset error or amplitude error, a technique is known which suppresses random noise by a means for, for example, collecting a number of peak values and performing exponential smoothing (U.S. Pat. No. 5,581,488 and Japanese Patent No. 2790862). However, to collect a large number of peak values, the moving distance needs to be long. Hence, the error correction unit cannot follow a local offset error or amplitude error.

### SUMMARY OF THE INVENTION

The present invention provides a technique that is advantageous for, for example, accurately and quickly computing the position or angle of a target object.

One of aspects of the present invention provides; a signal processing apparatus which computes a position or angle of a target object based on a first phase signal (A), a first reversed phase signal (A′) having a phase opposite to that of the first phase signal (A), a second phase signal (B) having a phase different from that of the first phase signal (A), and a second reversed phase signal (B′) having a phase opposite to that of the second phase signal (B) which are provided by a detecting apparatus that detects the position or angle of the target object, comprising a first computing unit which computes (A−A′)/(A+A′) as a cosine signal and (B−B′)/(B+B′) as a sine signal, and a second computing unit which computes the position or angle of the target object based on the cosine signal and the sine signal.

Further features of the present invention will become apparent from the following description of exemplary embodiments with reference to the attached drawings.

### BRIEF DESCRIPTION OF THE DRAWINGS

FIG. 1 is a block diagram showing the schematic arrangement of a signal processing apparatus according to the embodiment of the present invention; and

FIG. 2 is a timing chart showing two-phase periodic signals.

### DESCRIPTION OF THE EMBODIMENTS

The embodiment of the present invention will now be described with reference to the accompanying drawings.

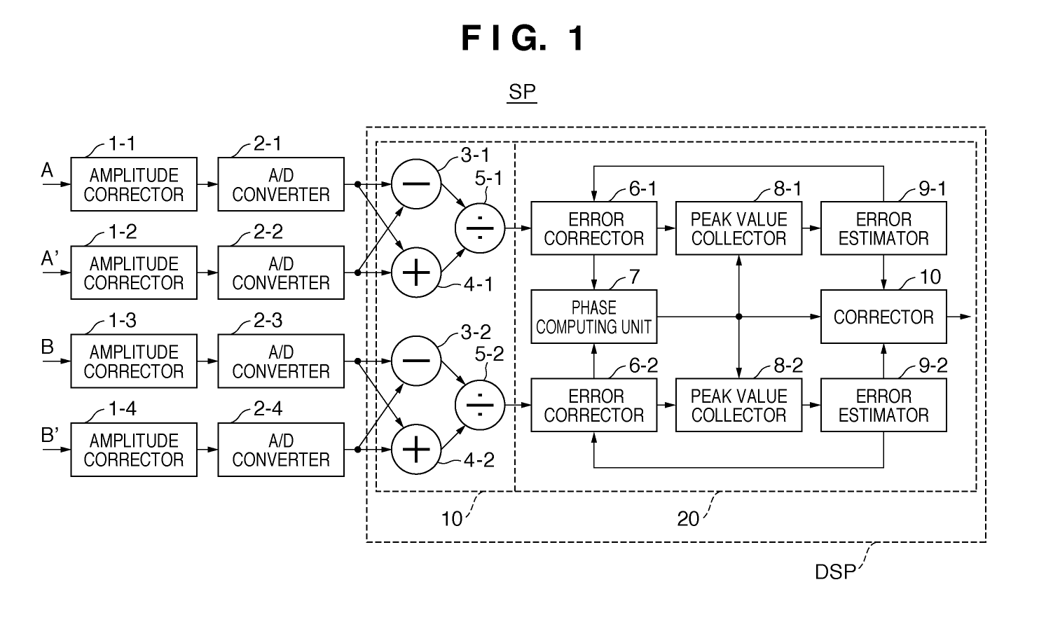

FIG. 1 is a block diagram showing the schematic arrangement of a signal processing apparatus according to the embodiment of the present invention. A signal processing apparatus SP according to the embodiment of the present invention receives periodic signals A, A′, B, and B′ provided by a detecting apparatus (e.g., encoder or laser interferometer) which detects the position or angle of a target object. The periodic signals A, A′, B, and B′ change their phases in accordance with the position or angle of the target object. The periodic signals A and B are sinusoidal signals having a phase difference (ideally a phase difference of 90°). The periodic signals A′ and B′ are signals having phases opposite to those of the periodic signals A and B. That is, the periodic signals A′ and B′ are signals having a phase difference of 180° with respect to the periodic signals A and B. The periodic signal A can be regarded as a first phase signal, the periodic signal A′ as a first reversed phase signal, the periodic signal B as a second phase signal, and the periodic signal B′ as a second reversed phase signal.

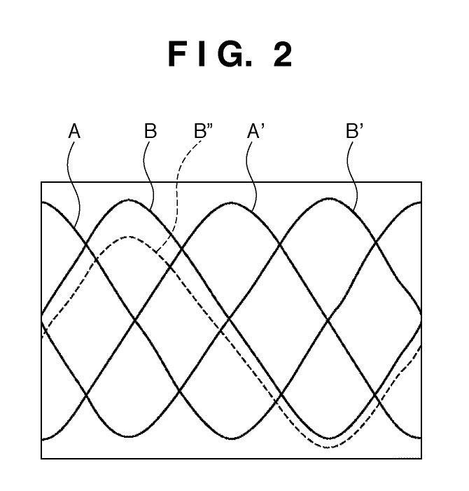

These periodic signals are detected by different photoreceivers in the detecting apparatus. By appropriately designing the optical system, the photoreceivers detect the periodic signals A, A′, B, and B′ as shown in FIG. 2 in accordance with the position or angle of the target object. The lower end of FIG. 2 indicates the zero level (i.e., the signal level when no light is incident at all). The upper end of FIG. 2 indicates the maximum signal level (i.e., the designed maximum level in the electronic circuit).

When amplitude modulation noise e is superimposed on the periodic signals A, A′, B, and B′, each of the periodic signals A, A′, B, and B′ changes its value to the product of the signal value shown in FIG. 2 and a coefficient (1+e). The value e is a very small positive or negative value representing noise. It can be a random value containing various frequency components. The amplitude modulation noise can be generated due to, for example, fluctuations in the power supply voltage and the intensity of light generated by a light source in the detecting apparatus. Hence, coefficients having identical values can be superimposed on all the periodic signals A, A′, B, and B′.

Assume that in the detecting apparatus, the sensitivity of the photoreceiver corresponding to the periodic signal B or the amplification factor of an amplifier for amplifying the output from the photoreceiver is low. In this case, the periodic signal B can proportionally decrease as indicated by, for example, B″ (dotted line) in FIG. 2. If the signal B″ is directly processed, the amplitude modulation noise cannot effectively be removed. To avoid this, the amplification factor can be adjusted at the first stage of the signal processing apparatus SP to make the amplitude equal to those of other periodic signals.

In the signal processing apparatus SP shown in FIG. 1, amplitude correctors 1-1 to 1-4 which form an amplitude correcting unit compensate for the sensitivity difference between the photoreceivers in the detecting apparatus or the amplification factor difference between the amplifiers. The amplitude correctors 1-1 to 1-4 output periodic signals whose amplitudes are corrected so as to make the amplitudes of the periodic signals A, A′, B, and B′ coincide with each other. For example, when the combination of the detecting apparatus and the signal processing apparatus SP is determinate, the amplification factors of the amplitude correctors 1-1 to 1-4 can be adjusted by a means such as a trimmer (trimming potentiometer) or laser trimming. If the type of the detecting apparatus to be connected to the signal processing apparatus SP is indeterminate, the amplification factors of the amplitude correctors 1-1 to 1-4 can be adjusted individually using, for example, a digital trimmer. Alternatively, multipliers may be added to correct the amplitudes by multiplying digital data after A/D conversion of A/D converters 2-1 to 2-4 by constants.

For the descriptive convenience, both the periodic signals which have undergone amplitude correction of the amplitude correctors 1-1 to 1-4 and the periodic signals which are digital data converted by the A/D converters 2-1 to 2-4 will also be referred to as the periodic signals A, A′, B, and B′ hereinafter.

The periodic signals output from the amplitude correctors 1-1 to 1-4 are converted into digital data by the A/D converters 2-1 to 2-4 and processed by a digital signal processor DSP. The digital signal processor DSP can be constituted by, for example, using a dedicated circuit, installing software in a microprocessor, or programming an FPGA (Field Programmable Gate Array).

The digital signal processor DSP includes a first computing unit 10 and a second computing unit 20. The first computing unit 10 computes (A−A′)/(A+A′) as a cosine signal and (B−B′)/(B+B′) as a sine signal. The second computing unit 20 computes the position or angle of the target object based on the cosine signal and the sine signal.

The first computing unit 10 includes subtractors 3-1 and 3-2, adders 4-1 and 4-2, and dividers 5-1 and 5-2. The subtractor 3-1 receives the periodic signals A and A′ converted into digital data and computes (A−A′), that is, the difference between the periodic signals A and A′. The adder 4-1 receives the periodic signals A and A′ converted into digital data and computes (A+A′), that is, the sum of the periodic signals A and A′. The divider 5-1 receives (A−A′) and (A+A′) and computes the ratio (A−A′)/(A+A′)=a. The subtractor 3-2 receives the periodic signals B and B′ converted into digital data and computes (B−B′), that is, the difference between the periodic signals B and B′. The adder 4-2 receives the periodic signals B and B′ converted into digital data and computes (B+B′), that is, the sum of the periodic signals B and B′. The divider 5-2 receives (B−B′) and (B+B′) and computes the ratio (B−B′)/(B+B′)=b.

Assume that the amplitude modulation noise e is superimposed on the periodic signals A, A′, B, and B′, that is, the periodic signals A, A′, B, and B′ are multiplied by (1+e). The noise e is removed from the signals a and b output from the dividers 5-1 and 5-2, as is apparent from

$$\{ ( 1 + e ) A - ( 1 + e ) {A}^{′} \} / \{ ( 1 + e ) A + ( 1 + e ) {A}^{′} \} = \frac{( A - {A}^{′} )}{( A + {A}^{′} )} = a$$

$$\{ ( 1 + e ) B - ( 1 + e ) {B}^{′} \} / \{ ( 1 + e ) B + ( 1 + e ) {B}^{′} \} = \frac{( B - {B}^{′} )}{( B + {B}^{′} )} = b$$

where a is a sinusoidal periodic signal which can be regarded as a cosine signal, and b is a sinusoidal periodic signal which has a phase difference of 90° with respect to the signal a and can be regarded as a sine signal.

The second computing unit 20 receives the cosine signal a and the sine signal b output from the dividers 5-1 and 5-2, respectively, and performs correction computation and arctangent computation in accordance with known methods. FIG. 1 illustrates an arrangement example of the second computing unit 20. A first error corrector 6-1 corrects the error of the cosine signal a using an error estimated value to generate a corrected cosine signal. A second error corrector 6-2 corrects the error of the sine signal b using an error estimated value to generate a corrected sine signal. In many cases, an offset error which is a positive/negative unbalance component of each of the cosine signal a and the sine signal b and an amplitude error which is the amplitude difference between the cosine signal a and the sine signal b are removed at this stage.

The operation of the second computing unit 20 will be described below in more detail. The first and second error correctors 6-1 and 6-2 receive the cosine signal a and the sine signal b, respectively, and generate a cosine signal A* and a sine signal B* which have undergone error correction based on estimated offset errors Z_{A} and Z_{B} and amplitudes G_{A} and G_{B} in accordance with

A*=(a−Z_{A})/G_{A}

B*=(b−Z_{B})/G_{B}

A phase computing unit 7 performs arctangent computation (i.e., atan^{-′}^{_{−}} (A*/B*)) using the cosine signal A* and the sine signal B* which have undergone error correction, thereby outputting information representing the position or angle of the target object.

Peak value collectors 8-1 and 8-2 collect the maximum and minimum values of the cosine signal A* and the sine signal B*, respectively. The cosine signal A* is maximized at 0° and minimized at 180°. It is therefore possible to estimate an amplitude G_{A}* of the cosine signal A* by subtracting the value of the cosine signal A* at 180° from the value at 0° (i.e., by calculating 2G_{A}*). The average of the maximum and minimum values is the offset error Z_{A}. The sine signal is maximized at 90° and minimized at 270°. Hence, it is possible to estimate the errors (amplitude G_{B}* and Z_{B}*) of the sine signal in accordance with the same procedure.

The cosine signal A* is a normalized signal, and ideally, G_{A}* is 1, and Z_{A}* is 0. However, if the estimated values of the offset errors Z_{A} and Z_{B} and the amplitudes G_{A} and G_{B} used by the first and second error correctors 6-1 and 6-2 for normalization include errors, offsets from the ideal values can occur. Correcting the estimated values of the offset errors Z_{A} and Z_{B} and the amplitudes G_{A} and G_{B} to be used for normalization using some or all of the offsets makes it possible to always maintain correct estimated values.

As described above, the amplitude modulation noise influences not phase computation using the signal ratio but the peak values. Without removing the amplitude modulation noise, the noise influences the error correcting unit and impedes accurate error correction. Averaging a number of peak values enables to suppress the influence of noise. In this case, however, the response to variations in the error mixing amount degrades.

According to the embodiment of the present invention, it is possible to improve both accuracy and response by removing amplitude modulation noise before arctangent computation. This allows requirements for accuracy improvement in the field of position and angle measurement to be easily met. The arrangement for removing the amplitude modulation noise can be implemented by a simple computing unit including, for example, subtractors, adders, and dividers.

Note that correction of offset errors and amplitude errors has been described above as an example of the error correction technique. However, various other error removing techniques are known nowadays, and the amplitude modulation noise removal is expected to have the effect of improving accuracy and response in these various error correction techniques as well.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2009-009365, filed Jan. 19, 2009, which is hereby incorporated by reference herein in its entirety.

What is claimed is:

1. A signal processing apparatus which computes a position or angle of a target object based on a first phase signal (A), a first reversed phase signal (A′) having a phase opposite to that of the first phase signal (A), a second phase signal (B) having a phase different from that of the first phase signal (A), and a second reversed phase signal (B′) having a phase opposite to that of the second phase signal (B) which are provided by a detecting apparatus that detects the position or angle of the target object, comprising:
a first computing unit which computes (A−A′)/(A +A′) as a cosine signal and (B−B′)/(B+B′) as a sine signal; and
a second computing unit which computes the position or angle of the target object based on the cosine signal and the sine signal.

2. The apparatus according to claim 1, further comprising an amplitude correcting unit which makes amplitudes of the first phase signal (A), the first reversed phase signal (A′), the second phase signal (B), and the second reversed phase signal (B′) coincide with each other.

3. The apparatus according to claim 1, wherein the second computing unit comprises:
a first error corrector which corrects an error of the cosine signal to generate a corrected cosine signal;
a second error corrector which corrects an error of the sine signal to generate a corrected sine signal; and
a phase computing unit which performs arctangent computation based on the corrected cosine signal and the corrected sine signal.

4. The apparatus according to claim 3, wherein each of the first error corrector and the second error corrector corrects an offset error and an amplitude error.
